(19) United States
(12) Patent Application Publication
(10) Pub. No.: US 2009/0039962 A1
(43) Pub. Date: Feb. 12, 2009

(54) HIGH FREQUENCY POWER AMPLIFIER AND HIGH FREQUENCY HEATING DEVICE

(76) Inventors: Takashi UNO, Hyogo (JP); Kazuhiro YAHATA, Osaka (JP); Hiroyuki SAKAI, Kyoto (JP)

Correspondence Address: MCDERMOTT WILL & EMERY LLP, 600 13TH STREET, NW, WASHINGTON, DC, 20005-3096, US

(21) Appl. No.: 12/188,439

(22) Filed: Aug. 8, 2008

(30) Foreign Application Priority Data
Aug. 9, 2007 (JP) 2007-208276

(51) Int. Cl. H03F 3/60

(52) U.S. Cl. 330/286

(57) ABSTRACT

A high frequency power amplifier includes an amplification element, a harmonic control circuit, an output matching circuit, and a load resistor. A high frequency signal input from an input end is amplified in the amplification element, passes through the harmonic control circuit and the output matching circuit, and is then supplied to the load resistor. The harmonic control circuit includes a first dielectric resonator and a second dielectric resonator.

### BACKGROUND OF THE INVENTION

1. Field of the Invention

The present invention relates to high frequency power amplifiers and particularly relates to a high frequency power amplifier including a harmonic control circuit connected to an output end of an amplification element and to a microwave heating device for heating a to-be-heated object.

2. Description of Related Art

High frequency power amplifiers are devices for amplifying and outputting an input high frequency signal and are incorporated in high frequency oscillators, high frequency transmitters, and the like. The power consumption of the high frequency power amplifiers is so large that the high frequency power amplifiers consume almost all supplied power necessary for driving the high frequency oscillators and the high frequency transmitters, which obstructs reduction in power consumption.

To tackle this problem, studies for attaining high power efficiency in high frequency power amplifiers have been currently promoted in various research institutes with the aim of reducing the driving power for the high frequency oscillators and the high frequency transmitters.

As one of circuit design methods for improving power efficiency in a high frequency power amplifier, there is known a class F amplifier in which the load conditions of the fundamental wave and the harmonics of the high frequency signal are optimized to shape the time waveforms of the drain voltage and drain current applied to the output ends of the amplification elements, such as transistors, thereby reducing the power consumed in the amplification elements.

The class F amplifier is formed adding a harmonic processing circuit to a class B amplifier. When a sine-wave with the fundamental frequency is inputted at a gate terminal of a field effect transistor (FET) which operates in class B, the time waveform of the drain current is shaped half-wave. However, the time waveform of the drain voltage is a sine-wave so that the time waveforms of the drain voltage and drain current have overlapping region. On the other hand, the class F amplifier has a harmonic processing circuit which is short-circuited for even harmonic frequencies and is open-circuited for odd harmonic frequencies, so that the voltage waveform is shaped like a square wave. If the overlaps of the time waveforms of the drain voltage and the drain current are eliminated completely, the drain efficiency reaches theoretically 100%.

FIG. 10 shows one example of a circuit diagram of a conventional class F amplifier using a FET. In FIG. 10, the high frequency power amplifier is composed of a FET 1004 as an amplification element, strip lines 1005, 1006, 1007, an output matching circuit 1008 for the fundamental wave of an input signal, and a load resistor 1009. The strip line 1005 is connected to an output end B of the FET 1004 and has a length corresponding to one fourth of the wavelength (λ) of the fundamental wave of an input signal. Each of the strip lines 1006, 1007 which is opened at one end thereof (open stubs) is connected at the other end thereof to an output end A of the strip line 1005. Wherein, the reference numeral 1001 denotes an input end of the high frequency signal, 1002 denotes a DC power supply terminal for the drain bias, and 1003 denotes a choke inductor for cutting a high frequency signal.

A harmonic control circuit is composed of the strip line 1005 and the open stubs 1006, 1007. The line lengths of the strip lines 1005, the open stub 1006, and the open stub 1007 are lengths corresponding to λ/4, λ/8, and λ/12, respectively. Since the open stub 1006 has a line length corresponding to λ/8, the impedance at the point A is short-circuited for the second harmonic. Further, with the strip line 1005 with a line length corresponding to λ/4, the impedance at the point B as an output end of the FET 1004 is short-circuited for the second harmonic. With the strip line 1007 with a line length corresponding to λ/12, the impedance at the point A is short-circuited for the third harmonic. In addition, with the strip line 1005 with a line length corresponding to λ/4, the impedance at the point B as the output end of the FET 1004 is opened for the third harmonic.

### SUMMARY OF THE INVENTION

In practice, however, the dielectric constant of the printed circuit board forming open stubs and the like is so low that it is difficult to reduce the size of the harmonic control circuit composed of the microstrip lines.

Further, even with the use of a printed circuit board with high quality, the open stubs formed of microstrip lines have a low Q value of the resonance, around 100, and therefore, incorporation of the harmonic control circuit causes transmission loss to inhibit reduction in power consumption.

The present invention has its object of providing a high frequency power amplifier with a high power efficiency by realizing a small-sized harmonic control circuit with less transmission loss.

In order to solve the above problems, the present invention provides a first high frequency power amplifier including an amplification element for amplifying a high frequency input signal; and a harmonic control circuit connected to an output end of the amplification element and including a dielectric resonator.

According to the present invention, the dielectric constant of a dielectric used for the dielectric resonator is higher than that of resin used in the conventional printed circuit board. The higher the dielectric constant, the more the harmonic control circuit can be reduced in size. Further, the dielectric resonator can obtain 1000 or larger Q value of the resonance, thereby remarkably reducing the transmission loss in the harmonic control circuit to increase the power efficiency of the amplification element.

In a second high frequency power amplifier in accordance with the present invention, the harmonic control circuit includes a first dielectric resonator connected at one end thereof to the output end of the amplification element via a connection end and being opened at the other end thereof, and a phase lead of a second harmonic of the high frequency input signal from the connection end to the other end of the first dielectric resonator is adjusted so as to fall within a range of (2n₁−1)π/2±5% (n₁ is a natural number).

With the above arrangement, the impedance at the output end of the amplification element is short-circuited for the second harmonic of the fundamental wave of the input signal to satisfy the load circuit condition for controlling the second harmonic, so that the voltage waveform is shaped to increase the power efficiency of the amplification element.

In a third high frequency power amplifier in accordance with the present invention, the harmonic control circuit further includes a second dielectric resonator of which one end is connected to the output end of the amplification element via the connection end and of which the other end is grounded, and a phase lead of a fundamental wave of the high frequency input signal from the other end of the first dielectric resonator to the other end of the second dielectric resonator is adjusted so as to fall within a range of (2n₂−1)π/2±5% (n₂ is a natural number).

The above arrangement reduces the reactance of the fundamental wave of the high frequency input signal in the harmonic control circuit. Accordingly, the impedance for the second harmonic at the output end of the amplification element can be short-circuited while the impedance for the fundamental wave of the high frequency input signal is little-affected by the harmonic control circuit.

In a fourth high frequency power amplifier in accordance with the present invention, the harmonic control circuit further includes a third dielectric resonator of which one end is connected to the output end of the amplification element via the connection end and of which the other end is opened, and a phase lead of the fundamental wave of the high frequency input signal from the other end of the first dielectric resonator to the other end of the third dielectric resonator is adjusted so as to fall within a range of n₃π±5% (n₃ is a natural number).

The above arrangement reduces the reactance of the fundamental wave of the high frequency input signal in the harmonic control circuit. Accordingly, the impedance for the second harmonic at the output end of the amplification element can be short-circuited while the impedance for the fundamental wave of the high frequency input signal is little-affected by the harmonic control circuit.

In a fifth high frequency power amplifier in accordance with the present invention, the harmonic control circuit includes a fourth dielectric resonator of which one end is connected to the output end of the amplification element via a connection end and of which the other end is grounded, and a phase lead of a second harmonic of the high frequency input signal from the connection end to the other end of the fourth dielectric resonator is adjusted so as to fall within a range of (2n₄−1)π±5% (n₄ is a natural number).

The above arrangement allows the impedance at the output end of the amplification element to be short-circuited for the second harmonic of the high frequency input signal. Therefore, the harmonic control circuit satisfies the load circuit condition for controlling the second harmonic.

In a sixth high frequency power amplifier in accordance with the present invention, the harmonic control circuit includes: phase rotation means connected between the output end of the amplification element and a connection end; and a fifth dielectric resonator of which one end is connected to the output end of the amplification element via the connection end and of which the other end is opened, and a phase lead of a third harmonic of the high frequency input signal from the connection end to the other end of the fifth dielectric resonator is adjusted so as to fall within a range of (2n₅−1)π/2±5% (n₅ is a natural number except 3m−1 where m is a natural number).

With the above arrangement, the impedance for the third harmonic of the fundamental wave of the high frequency input signal is short-circuited at the connection end of the fifth dielectric resonator.

Further, when the phase of the short-circuited impedance at the connection end of the fifth dielectric resonator is rotated by 180 degrees, 540 degrees, 900 degrees, . . . by the phase rotation means to be the open-circuited impedance at the output end of the amplification element, the load circuit condition for controlling the third harmonic is satisfied. As a result, the voltage waveform is shaped to increase the power efficiency of the high frequency power amplifier.

In a seventh high frequency power amplifier in accordance with the present invention, the harmonic control circuit further includes a sixth dielectric resonator of which one end is connected to the output end of the amplification element via the connection end and of which the other end is grounded, and a phase lead of a fundamental wave of the high frequency input signal from the other end of the fifth dielectric resonator to the other end of the sixth dielectric resonator is adjusted so as to fall within a range of (2n₆−1)π/2±5% (n₆ is a natural number).

The above arrangement reduces the reactance of the fundamental wave of the high frequency input signal in the harmonic control circuit. Accordingly, the impedance for the third harmonic at the output end of the amplification element can be opened while the impedance for the fundamental wave of the high frequency input signal is little-affected by the harmonic control circuit.

In an eighth high frequency power amplifier in accordance with the present invention, the harmonic control circuit further includes a seventh dielectric resonator of which one end is connected to the output end of the amplification element via the connection end and of which the other end is opened, and a phase lead of a fundamental wave of the high frequency input signal from the other end of the fifth dielectric resonator to the other end of the seventh dielectric resonator is adjusted so as to fall within a range of n₇π±5% (n₇ is a natural number).

The above arrangement reduces the reactance of the fundamental wave of the high frequency input signal in the harmonic control circuit. Accordingly, the impedance for the third harmonic at the output end of the amplification element can be opened while the impedance for the fundamental wave of the high frequency input signal is little-affected by the harmonic control circuit.

In a ninth high frequency power amplifier in accordance with the present invention, the harmonic control circuit includes: phase rotation means connected between the output end of the amplification element and a connection end; and an eighth dielectric resonator of which one end is connected to the output end of the amplification element via the connection end and of which the other end is grounded, and a phase lead of a third harmonic of the high frequency input signal from the connection end to the other end of the eighth dielectric resonator is adjusted so as to fall within a range of n₈π±5% (n₈ is a natural number except multiples of 3).

With the above arrangement, the impedance for the third harmonic of the high frequency input signal is short-circuited at the connection end of the eighth dielectric resonator.

Further, when the phase of the short-circuited impedance for the third harmonic at the connection end of the eighth dielectric resonator is rotated by 180 degrees, 540 degrees, 900 degrees, . . . by the phase rotation means to be the open-circuited impedance at the output end of the amplification element, the load circuit condition for controlling the third harmonic is satisfied. As a result, the voltage waveform is shaped to increase the power efficiency of the high frequency power amplifier.

In a tenth high frequency power amplifier in accordance with the present invention, the harmonic control circuit further includes a ninth dielectric resonator of which one end is connected to the output end of the amplification element via the connection end and of which the other end is grounded, and a phase lead of a fundamental wave of the high frequency input signal from the other end of the eighth dielectric resonator to the other end of the ninth dielectric resonator is adjusted so as to fall within a range of n₉π±5% (n₉ is a natural number).

The above arrangement reduces the reactance of the fundamental wave of the high frequency input signal in the harmonic control circuit. Accordingly, the impedance for the third harmonic is opened at the output end of the amplification element while the impedance for the fundamental wave of the high frequency input signal is little-affected by the harmonic control circuit.

In an eleventh high frequency power amplifier in accordance with the present invention, the harmonic control circuit includes a tenth dielectric resonator of which one end is connected to the output end of the amplification element via the connection end and of which the other end is opened, and a phase lead of a fundamental wave of the high frequency input signal from the other end of the eighth dielectric resonator to the other end of the tenth dielectric resonator is adjusted so as to fall within a range of (2n₁₀−1)π/2±5% (n₁₀ is a natural number).

The above arrangement reduces the reactance of the fundamental wave of the high frequency input signal in the harmonic control circuit. Accordingly, the impedance for the third harmonic at the output end of the amplification element is opened while the impedance for the fundamental wave of the high frequency input signal is little-affected by the harmonic control circuit.

In a twelfth high frequency power amplifier in accordance with the present invention, the phase rotation means is a transmission line of which length is adjusted so as to correspond to a length in a range of (2n₁₁−1)λ/4 (n₁₁ is a natural number). Wherein λ is a wave length of a fundamental wave of the high frequency input signal.

According to the above arrangement, the impedance for the harmonic component short-circuited by the dielectric resonator at the connection end of the dielectric resonator can be short-circuited for the even harmonic while being opened to the odd harmonic at the output end of the amplification element.

For example, a microstrip line with a length corresponding to λ/4 where n₁₁ is 1 rotates the phase of the fundamental wave of a high frequency input signal by 180 degrees. Further, the microstrip line rotates the second harmonic, which has a wavelength of one half of the fundamental wave, by 360 degrees corresponding to the double of the phase rotation angle of the fundamental wave and rotates the third harmonic by 540 degrees corresponding to the triple of that of the fundamental wave. Similarly, it rotates the fourth and subsequent higher harmonics, so that the impedances at the output end of the amplification element are short-circuited for the even harmonics short-circuited at the connection end of the dielectric resonators while being opened to the odd harmonics short-circuited at the connection end thereof. This satisfies the load circuit conditions for controlling the harmonics. Even in the case where n₁₁ is 2, which means that the phase rotation angle is tripled, the impedance at the output end of the amplification element is short-circuited for the even harmonics while being opened to the odd harmonics, as well as the case where n₁₁ is 1.

A high frequency heating device in accordance with the present invention includes a high frequency oscillator: a high frequency power amplifier including: an amplification element which amplifies a high frequency signal output from the high frequency oscillator; and a harmonic control circuit including a dielectric resonator and connected to an output end of the amplification element; a container for heating an object therein by radiating inside thereof with the high frequency signal amplified in the high frequency power amplifier; and a high frequency radiator which radiates inside of the container with the high frequency signal output from the high frequency power amplifier.

High frequency heating devices require a high output power of 100 W or higher as an output of a high frequency power amplifier to heat objects. The transmission loss in a harmonic control circuit becomes large in association with the output of the high frequency power amplifier, which means that reduction in transmission loss is demanded in the harmonic control circuit. The high frequency power amplifier in accordance with the present invention uses the dielectric resonators with a high Q value of the resonance in the a harmonic control circuit, thereby remarkably reducing the transmission loss in the harmonic control circuit. Namely, the high frequency power amplifier in accordance with the present invention is useful for the high power application with output power of 100 W or higher, such as in a high frequency heating device and the like.

### BRIEF DESCRIPTION OF THE DRAWINGS

FIG. 1A is a side view showing a dielectric resonator in accordance with Embodiment 1 of the present invention, and FIG. 1B is a sectional view showing the dielectric resonator in accordance with Embodiment 1 of the present invention.

FIG. 2 is a circuit diagram of a high frequency power amplifier in accordance with Embodiment 2 of the present invention.

FIG. 3 is a circuit diagram of a high frequency power amplifier in accordance with Embodiment 3 of the present invention.

FIG. 4 is a circuit diagram of a high frequency power amplifier in accordance with Embodiment 4 of the present invention.

FIG. 5 is a circuit diagram of a high frequency power amplifier in accordance with Embodiment 5 of the present invention.

FIG. 6 is a circuit diagram of a high frequency power amplifier in accordance with Embodiment 6 of the present invention.

FIG. 7 is a circuit diagram of a high frequency power amplifier in accordance with Embodiment 7 of the present invention.

FIG. 8 is a circuit diagram of a high frequency power amplifier in accordance with Embodiment 8 of the present invention.

FIG. 9 is a circuit diagram of a high frequency power amplifier in accordance with Embodiment 9 of the present invention.

FIG. 10 is a circuit diagram of a conventional high frequency power amplifier.

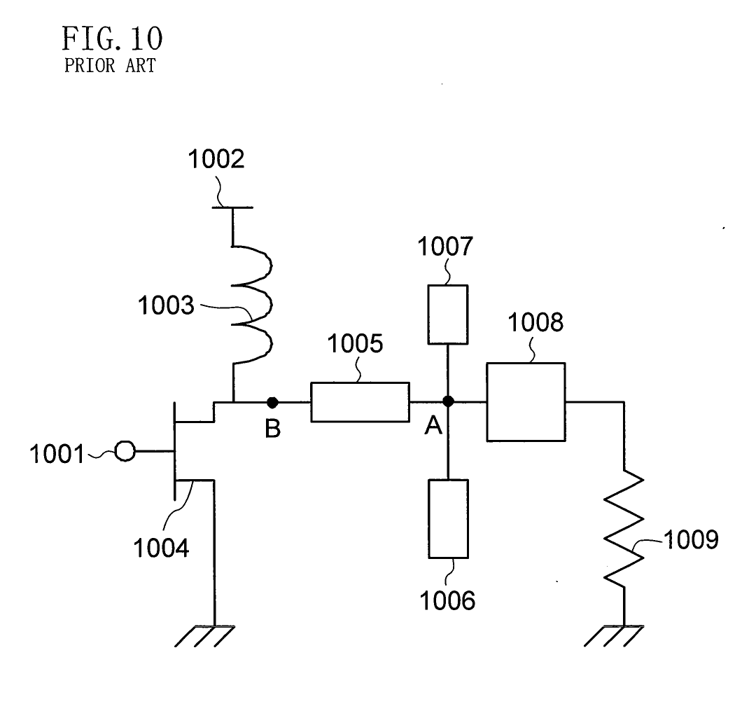

FIG. 11 is a diagram schematically showing a high frequency heating device in accordance with the present invention.

### BEST MODE FOR CARRYING OUT THE INVENTION

Embodiments of the present invention will be described below with reference to the accompanying drawings. In the drawings, the same reference numerals are assigned to components having substantially the same functions for the sake of simple description. It should be noted that the present invention is not limited to the following embodiments.

### Embodiment 1

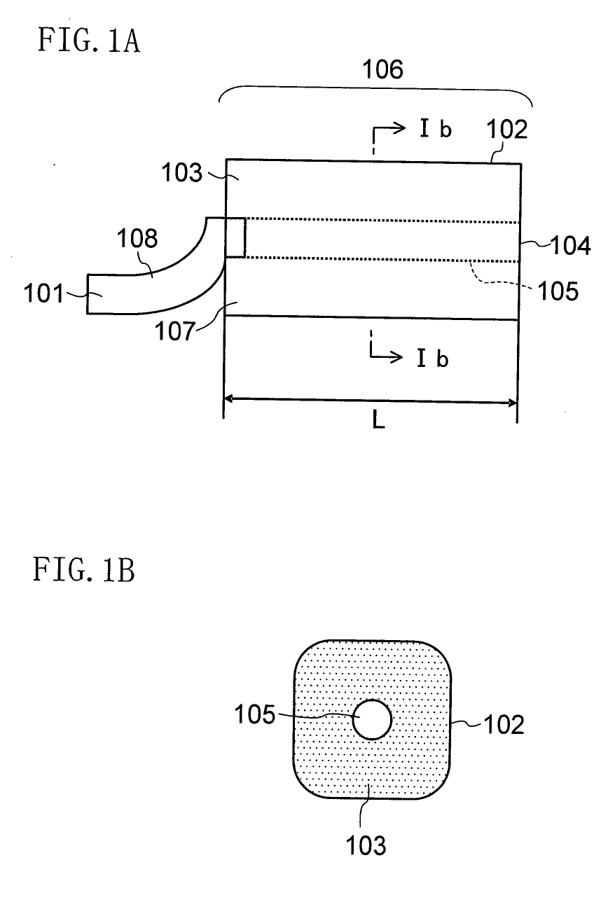

FIG. 1A and FIG. 1B are a side view and a sectional view, respectively, of a dielectric resonator in accordance with the present invention.

In a dielectric resonator 106, as shown in FIG. 1A and FIG. 1B, a strip line 105 as a signal line is covered with a dielectric material 103 and the dielectric material 103 is covered with a grounded external conductor 102.

Accordingly, when an electromagnetic wave is input to the strip line 105, the dielectric resonator 106 confines the input electromagnetic wave, so that the dielectric resonator 106 can have excellent resonance characteristics with a Q value of the resonance of 1000 or more.

In general, the transmission loss in a harmonic control circuit for controlling the harmonics of an input electromagnetic wave is determined according to the Q value of resonance.

In the present invention, a harmonic control circuit has dielectric resonators with a high Q value of resonance when compared with stubs on a conventional printed circuit board, thereby reducing the transmission loss.

An end wall 104 of the dielectric resonator 106 is grounded or opened. An electromagnetic wave input from a connection end 101 to the signal line forms an amplitude node at the end wall 104 when the end wall 104 is grounded and forms an amplitude loop thereat when the end wall 104 is opened. Herein, when the end wall 104 is grounded and the axial length L of the dielectric resonator is adjusted so as to correspond to one half of the wavelength (λ) of the input signal, an amplitude node is formed at the end wall 104 while an amplitude node is formed at a input terminal plane 107, thereby short-circuiting the impedance at the input terminal plane 107 on the input side.

In contrast, when the end wall 104 is opened and the axial length L of the dielectric resonator is adjusted so as to correspond to λ/4, an amplitude loop is formed at the end wall 104 while an amplitude node is formed at the input terminal plane 107, thereby short-circuiting the impedance at the input terminal plane 107. Herein, the dielectric resonator 106 is connected to the connection end 101 through a connection terminal 108. Therefore, a phase lead in the connection terminal 108 must be taken into consideration in the case where a input signal is the high frequency wave. Specifically, it is necessary for short-circuiting the impedance at the connection end 101 to adjust the axial length L of the dielectric resonator 106 so that the sum of the phase lead in the connection terminal 108 and in the dielectric resonator 106 becomes π or π/2. This adjustment have only to adjust the phase lead from the connection end 101 to the end wall 104 of the dielectric resonator 106 so as to fall within the range of π or π/2±5%.

Other than such adjustment of the axial length L of the dielectric resonator for adjusting the phase lead, the phase lead may be adjusted in such a manner that the connection end 101 is connected to the signal line via a capacitor with adjusted capacitance. Capacitors have an effect of phase lagging to achieve adjustment of the total phase lead.

The axial length L of the dielectric resonator 106 can be calculated from the signal frequency f₀ and the dielectric constant ∈r of the dielectric material 103. For example, for adjusting the axial length L of the dielectric resonator 106 so as to correspond to λ/4 with the end wall 104 opened, the axial length L of the dielectric resonator 106 can be calculated by Expression 1:

L_{λ/4}=C/(4F₀√∈r) (Expression 1).

Wherein, C is a transmission speed of an electromagnetic wave in the air.

As a dielectric material used for a dielectric resonator, various materials are put into practical use, such as MgCaTiO₃ with a dielectric constant of around 20, BaO—PbO—Nb₂O₃—TiO₂ with a dielectric constant of around 90. In contrast, the dielectric constants of general dielectric materials used for printed circuit boards, such as epoxy resin and the like are around 3. Accordingly, the axial length of the dielectric resonator becomes shorter than the line length of an open stub formed of a microstrip line on a printed circuit board, leading to size reduction of a high frequency power amplifier including a harmonic control circuit.

It is noted that the practical range of a high frequency signal input to the dielectric resonator is preferably 5 GHz or lower, but a signal at a further higher frequency may be input.

### Embodiment 2

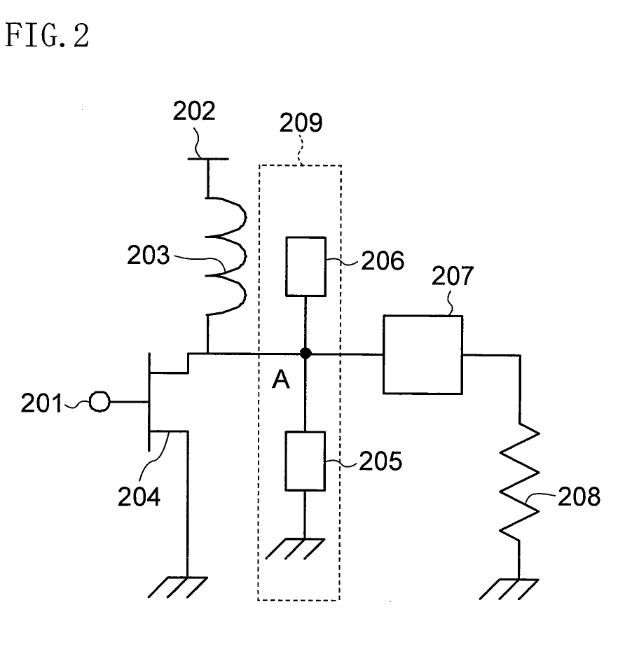

FIG. 2 is a circuit diagram of a high frequency power amplifier in accordance with Embodiment 2 of the present invention. The high frequency power amplifier of FIG. 2 includes an amplification element 204, such as a transistor or the like, a harmonic control circuit 209, an output matching circuit 207, and a load resistor 208. Reference numeral 201 denotes an input end of a high frequency signal, 202 denotes a DC bias end for driving the amplification element 204, and 203 denotes a choke inductor for cutting a high frequency.

The high frequency signal input from the input end 201 is amplified in the amplification element 204, passes through the harmonic control circuit 209 and the output matching circuit 207, and is supplied to the load resistor 208.

The output matching circuit 207 solves impedance mismatch between the output end of the output matching circuit 207 and the load resistor 208 and usually adjusts the impedance on the amplification element side so as to be 50Ω at the output end of the output matching circuit 207.

The harmonic control circuit 209 is composed of a first dielectric resonator 206 and a second dielectric resonator 205. Wherein, the first dielectric resonator 206 is connected at one end thereof to the output end of the amplification element 204 via a connection end A and is opened at the other end. The axial length of the first dielectric resonator 206 is adjusted so as to correspond to λ/8 where λ is the fundamental wavelength of the high frequency input signal. The second dielectric resonator 205 is connected at one end thereof to the output end of the amplification element 204 via the connection end A and is grounded at the other end. The axial length of the second dielectric resonator 205 is adjusted so as to correspond to λ/8.

When the wavelength of the second harmonic is λ₂, the axial length of the first dielectric resonator 206, which corresponds to λ/8, corresponds to λ₂/4, so that the second harmonic component forms an amplitude loop at the open end while forming an amplitude node at the connection end A. Accordingly, the impedance at the connection end A for the second harmonic is short-circuited, so that the load circuit condition for controlling the second harmonic is satisfied.

Similarly to the impedances for the second harmonic, the impedances for the sixth, tenth, . . . , 2(2m−1)-th (m is a natural number) harmonics of the fundamental wave of the high frequency input signal is short-circuited to satisfy the load circuit conditions for controlling the sixth, tenth, . . . , 2(2m−1)-th harmonics. As a result, the voltage waveform is shaped, thereby improving the power efficiency of the high frequency power amplifier.

Further, even when the axial length of the first dielectric resonator 206 is adjusted so as to correspond to (2n₁−1)λ/8 (n₁ is a natural number), an amplitude loop is formed at the open end while an amplitude node is formed at the connection end A, thereby short-circuiting the impedances for the second, sixth, tenth, . . . , 2(2m−1)-th harmonics at the connection end A. Therefore, when a signal frequency is much higher, the value of n₁ should be enlarged so as to realize the dielectric resonator 206 in a practical size.

Further, with the total axial length of the first and second dielectric resonators 206, 205 corresponding to λ/4, the fundamental wave forms an amplitude loop at the open end of the first dielectric resonator 206 while forming an amplitude node at the grounded end of the second dielectric resonator 205 for resonance. This resonance allows the impedance for the fundamental wave at the connection end A to be almost infinite to allow the fundamental wave pass through the harmonic control circuit 209. Accordingly, the impedances for the second, sixth, tenth, . . . , 2(2m−1)-th harmonics can be short-circuited while the impedance for the fundamental wave of the high frequency input signal is little-affected by the harmonic control circuit 209.

Herein, if the total axial length of the first and second dielectric resonators 206, 205 corresponds to (2n₂−1)λ/4 (n₂ is a natural number), the fundamental wave forms an amplitude loop at the open end of the first dielectric resonator 206 while forming an amplitude node at the grounded end of the second dielectric resonator 205 for resonance.

Accordingly, enlarging the value of n₂ even when the frequency of the high frequency input signal is extremely high or the like leads to realization of dielectric resonators with a practical length.

The second harmonic can be controlled even when the harmonic control circuit 209 is composed of the first dielectric resonator 206 without the second dielectric resonator 205.

In the case where the connection terminal 108 of a metal material or the like is used as in Embodiment 1 for connection without direct connection between the connection point A and a dielectric resonator, the axial length of the dielectric resonator and/or the capacitance of an additional capacitor may be adjusted with the phase lead in the connection terminal 108 taken into consideration. The length of the first dielectric resonator 206 corresponding to (2n₁1)λ/8 corresponds to (2n₁−1)π/2 as the phase lead of the second harmonic. In the case where the first dielectric resonator 206 is connected with the use of the connection terminal 108 in the present embodiment, the impedance for the second harmonic must be short-circuited at the connection end A with the phase lead in the connection terminal 108 taken into consideration. To do so, it is preferable to adjust the phase lead of the second harmonic from the connection end A to the open end of the first dielectric resonator 206 to fall within the range of (2n₁−1)π/2±5%.

The length corresponding to (2n₂−1)λ/4, namely, the total axial length of the first dielectric resonator 206 and the second dielectric resonator 205 corresponds to (2n₂−1)π/2 as the phase lead of the fundamental wave. In the case where the first dielectric resonator 206 and the second dielectric resonator 205 are connected to the connection end A with the use of the connection terminals 108 or via additional capacitors in the present embodiment, each phase lead in the connection terminals 108 to the first and second dielectric resonators 206, 205 must be considered. Specifically, in order to short-circuit the impedance for the second harmonic under little-affected on the impedance of the fundamental wave, it is preferable to adjust the axial lengths of the dielectric resonators and the capacitance of the additional capacitors so that the sum of the phase lead from the open end of the first dielectric resonator 206 to the grounded end of the second dielectric resonator 205 including each phase lead of the fundamental wave of the connection terminals 108 to the dielectric resonators and the additional capacitors to fall within the range of (2n₂−1)π/2±5%.

The output matching circuit 207 is connected to the output end of the amplification element 204 via the connection end A in the present embodiment but may be interposed between the connection end A and the output end of the amplification element 204. To do so, it is preferable for short-circuiting the impedance at the output end of the amplification element 204 that a phase rotation means of a microstrip line or the like is formed between the output matching circuit 207 and the connection end A for setting the sum of the phase lead of the second harmonic at the output matching circuit 207 and the phase lead by the microstrip line from the output end of the output matching circuit 207 to the connection end A to be 2n₁₂π (n₁₂ is a natural number). The dielectric resonators can be mounted by soldering on a microstrip line or the like, which means that the phase lead can be controlled only by adjusting the position of the soldering.

### Embodiment 3

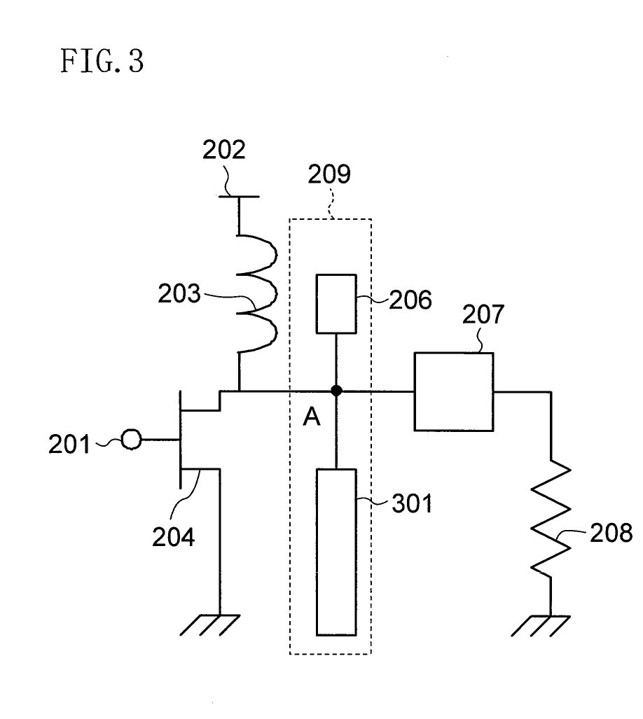

FIG. 3 is a circuit diagram of a high frequency power amplifier in accordance with Embodiment 3 of the present invention. The difference from Embodiment 2 of the present invention lies in that the second dielectric resonator 205 is replaced by a third dielectric resonator 301. Herein, the third dielectric resonator 301 is connected at the one end thereof to the output end of the amplification element 204 via the connection end A and is opened at the other end, and the axial length thereof is adjusted so as to correspond to 3λ/8.

As described in Embodiment 2 of the present invention, the first dielectric resonator 206 allows the impedances for the second, sixth, tenth, . . . , 2(2m−1)-th harmonics to be short-circuited.

Further, with the first and third dielectric resonators 206, 301 of which total axial length corresponds to λ/2, the fundamental wave forms an amplitude loop at the open end of the first dielectric resonator 206 while forming an amplitude loop at the open end of the third dielectric resonator 301 for resonance. According to this resonance, the impedance for the fundamental wave at the connection end A to be almost infinite, thereby allowing the fundamental wave to pass through the harmonic control circuit 209. Hence, the impedances for the second, sixth, tenth, . . . , 2(2m−1)-th harmonics are short-circuited while the impedance for the fundamental wave of the high frequency input signal is little-affected by the harmonic control circuit 209.

If the total axial length of the first and third dielectric resonators 206, 301 corresponds to n₃λ2 (n₃ is a natural number), the fundamental wave forms an amplitude loop at the open end of the first dielectric resonator 206 while forming an amplitude loop at the open end of the third dielectric resonator 301 for resonance. Accordingly, in the case where the signal frequency is high or the like, an increase in value of n₃ can lead to realization of a circuit in a practical size.

The total length of the first and third dielectric resonators 206, 301 corresponding to n₃λ/2 corresponds to n₃π as the phase lead of the fundamental wave. In the case where the first and third dielectric resonators 206, 301 are connected to the connection end A through the aforementioned connection terminals 108 or via additional capacitors in the present embodiment, it is preferable for allowing the impedance for the second harmonic to be short-circuited under little-affected on the impedance of the fundamental wave to adjust the axial lengths of the dielectric resonators and the capacitance of the additional capacitors so that the total phase lead of the fundamental wave from the open end of the first dielectric resonator 206 to the open end of the third resonator 301 falls within the range of n₃π±5% with the phase lead in each connection terminal 108 to the dielectric resonators and each capacitor taken into consideration.

### Embodiment 4

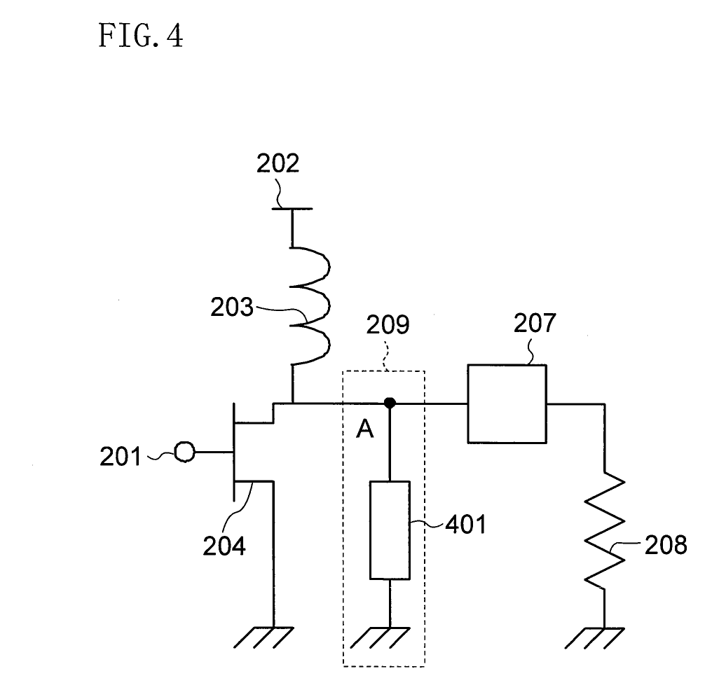

FIG. 4 is a circuit diagram of a high frequency power amplifier in accordance with Embodiment 4 of the present invention. Dislike Embodiments 2 and 3, Embodiment 4 provides, in the harmonic control circuit 209, only a fourth dielectric resonator 401 of which one end is connected to the connection end A, of which the other end is grounded, and of which axial length is adjusted so as to correspond to λ/4.

The axial length of the fourth dielectric resonator 401, which corresponds to λ/4, corresponds to λ₂/2 where the wavelength of the second harmonic is 2. Accordingly, the second harmonic wave forms an amplitude node at the grounded end while forming an amplitude node at the connection end A. This causes the impedance for the second harmonic to be short-circuited at the connection end A, with a result that the load circuit condition for controlling the second harmonic is satisfied. Similarly, the impedances for the fourth, sixth, . . . , 2m-th harmonics of the fundamental wave of the input signal are short-circuited, with a result that the load circuit conditions for controlling the fourth, sixth, . . . , 2m-th harmonics are satisfied. Hence, the voltage waveform is shaped to lead to implementation of a highly efficient high frequency power amplifier.

Further, with the fourth resonator 401 of which axial length corresponds to λ/4, the fundamental wave forms an amplitude node at the grounded end while forming an amplitude loop at the connection end A. Accordingly, the dielectric resonator 401 has an infinite impedance for the fundamental wave to allow the fundamental wave to pass through the harmonic control circuit 209. Hence, the impedances for the second, fourth, sixth, . . . , 2m-th harmonics, that is, for all of the even harmonics are short-circuited under little-affected on the impedance of the fundamental wave. In addition, even if the axial length of the fourth dielectric resonator 401 is adjusted so as to correspond to (2n₄−1)λ/4 (n₄ is a natural number), the second harmonic wave forms an amplitude node at the grounded end while forming an amplitude node at the connection end A. Accordingly, the impedances for all the even harmonics can be short-circuited. In addition, the fundamental wave forms an amplitude node at the grounded end while forming an amplitude loop at the connection end A so that the impedance of the fundamental wave at the connection end A is almost infinite. Hence, even in the case where the axial length of the dielectric resonator 401 becomes short due to a high signal frequency, an increase in value of n₄ can lead to realization of a circuit in a practical size.

The axial length of the fourth dielectric resonator 401 corresponding to (2n₄−1)λ/4 corresponds to (2n₄−1)π as the phase lead of the second harmonic and (2n₄−1)π/2 as that of the fundamental wave. In the case where the fourth dielectric resonator 401 is connected to the connection end A through the aforementioned connection terminal 108 or via an additional capacitor in the present embodiment, it is preferable for allowing the impedance for the second harmonic at the connection end A to be short-circuited to adjust the phase lead of the second harmonic from the connection end A to the grounded end of the fourth dielectric resonator 401 to fall within the range of (2n₄−1)π±5%. In other words, it is preferable to adjust the axial length of the dielectric resonator and the capacitance of the additional capacitor so that the total phase lead in the connection terminal 108, the fourth dielectric resonator 401, and the additional capacitor falls within the range of (2n₄−1)π±5%.

As described in Embodiment 2, the output matching circuit 207 may be provided between the connection end A and the output end of the amplification element 204. To do so, it is preferable for short-circuiting the impedance at the output end of the amplification element 204 to set the phase lead of the second harmonic between the output end of the amplification element 204 and the connection end A including the output matching circuit 207 to be 2n₁₂π. Provision of a phase rotation microstrip line at the output end of the output matching circuit 207 and fine adjustment of the position of the connection point A to the dielectric resonator 204 enable phase control.

### Embodiment 5

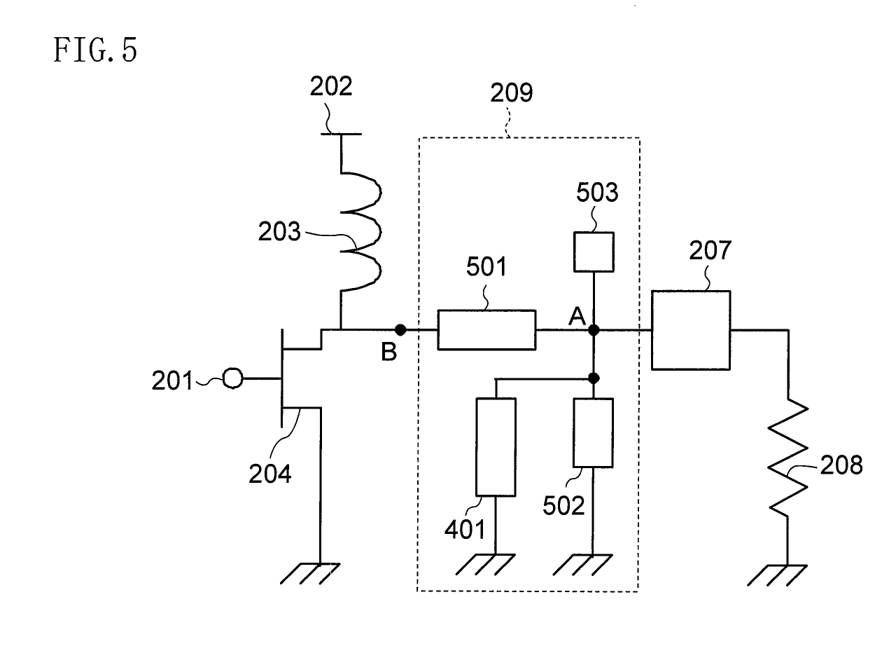

FIG. 5 is a circuit diagram of a high frequency power amplifier in accordance with Embodiment 5 of the present invention. In the present embodiment, the harmonic control circuit 209 includes a microstrip line 501 of which length is adjusted so as to correspond to λ/4, the fourth dielectric resonator 401, a fifth dielectric resonator 503, and a sixth dielectric resonator 502.

The microstrip line 501 is provided between the output end of the amplification element 204 and the connection end A. The fifth dielectric resonator 503 is connected at one end thereof to the connection end A, is opened at the other end thereof, and has an axial length adjusted so as to correspond to λ/12. The sixth dielectric resonator 502 is connected at one end thereof to the connection end A, is grounded at the other end thereof, and has an axial length adjusted so as to correspond to λ/6.

The axial length of the fifth dielectric resonator 503, which corresponds to λ/12, corresponds to λ₃/4 where the wavelength of the third harmonic is λ₃. Accordingly, the third harmonic wave forms an amplitude loop at the open end while forming an amplitude node at the connection end A. This causes the impedance for the third harmonic to be short-circuited at the connection end A to the dielectric resonator 503. Similarly, the impedances for the ninth, fifteenth, . . . , 3(2m−1)-th harmonics are short-circuited at the connection end A.

Further, as described in Embodiment 4, the effects by the fourth dielectric resonator 401 causes the impedances for the even harmonics to be short-circuited at the connection end A.

With the microstrip line 501 having a length corresponding to λ/4, the phases of the second harmonic wave and the third harmonic wave are rotated by 360 degrees and 540 degrees, respectively. Accordingly, the impedance of the harmonic control circuit 209 at an output end B of the amplification element 204 is short-circuited for the even harmonics short-circuited at the connection end A by the dielectric resonators and is opened to the odd harmonics short-circuited at the connection end A by the resonators. As a result, the load circuit conditions for controlling the harmonics are satisfied.

Further, with the fifth and sixth dielectric resonators 503, 502 of which total axial length corresponds to λ/4, the fundamental wave forms an amplitude loop at the open end of the fifth dielectric resonator 503 while forming an amplitude node at the grounded end of the sixth dielectric resonator 502 for resonance. According to this resonance, the impedance for the fundamental wave at the connection end A to be almost infinite to allow the fundamental wave to pass through the harmonic control circuit 209. Hence, the harmonics short-circuited at the connection end A by the dielectric resonators are controlled while the impedance for the fundamental wave of the high frequency input signal is little-affected by the harmonic control circuit 209.

Even if the axial length of the fifth dielectric resonator 503 is adjusted so as to correspond to (2n₅−1)λ/12 (n₅ is a natural number), the third harmonic wave forms an amplitude loop at the open end while forming an amplitude node at the connection end A. Accordingly, the impedances for the third, ninth, fifteenth, . . . , 3(2m−1)-th harmonics can be short-circuited at the connection end A. Hence, even in the case where the signal frequency is high to shorten the axial length of the dielectric resonators, an increase in value of n₅ can lead to realization of a circuit in a practical size.

Wherein, in the case where n₅ in (2n₅−1)λ/12 is 3m−1 (m is a natural number), namely, where the axial length of the fifth dielectric resonator 503 corresponds to (2m−1)λ/4, the axial length of the fifth dielectric resonator 503 corresponds to an odd multiple of λ/4. Accordingly, the fundamental wave in the fifth dielectric resonator 503 forms an amplitude loop at the open end while forming an amplitude node at the connection end A to the microstrip line 501 (phase rotation means) to inhibit the fundamental wave from passing through the harmonic control circuit 209. Therefore, n₅ must be prevented from being 3m−1.

Further, even if the microstrip line 501 is set to have a length corresponding to (2n₁₁−1)λ/4 (n₁₁ is a natural number), the phase rotation angle is multiplied by (2n₁₁−1). Accordingly, the impedance can be short-circuited for the even harmonics and be opened to the odd harmonics of the harmonics short-circuited at the connection end A by the dielectric resonators. Hence, even in the case where the axial lengths of the dielectric resonators are shortened due to a high signal frequency, an increase in value of n₁₁ an lead to realization of the harmonic control circuit 209 in a practical size.

Only required for the microstrip line 501 is phase rotation, and therefore, the microstrip line 501 may be a coplanar line, slot line, or the like or a lumped constant circuit.

The even harmonics may be controlled by the first dielectric resonator 206 rather than the fourth dielectric resonator 401.

When the total axial length of the fifth and sixth dielectric resonators 503, 502 corresponds to (2n₆−1)λ/4 (n₆ is a natural number), the fundamental wave forms an amplitude loop at the open end of the fifth dielectric resonator 503 while forming an amplitude node at the grounded end of the sixth dielectric resonator 502 for resonance. Accordingly, in the case where the signal frequency is high or the like, an increase in value of n₆ can lead to realization of a circuit in a practical size.

Even if the harmonic control circuit 209 is composed of the microstrip line 501, the fourth dielectric resonator 401, and the fifth dielectric resonator 503, the load circuit conditions for controlling all of the even harmonics and the third, ninth, fifteenth, 3(2m−1)-th harmonics are satisfied, and therefore, the sixth dielectric resonator 502 may not be necessarily provided.

The axial length of the fifth dielectric resonator 503 corresponding to (2n₅−1)λ/12 corresponds to (2n₅−1)π/2 as the phase lead of the third harmonic. In the case where the fifth dielectric resonator 503 is connected to the connection end A through the aforementioned connection terminal 108 or via an additional capacitor in the present embodiment, the phase lead in the connection terminal 108 and the capacitance of the additional capacitor must be taken into consideration. Specifically, it is preferable for allowing the impedance for the third harmonic to be short-circuited at the connection end A to adjust the axial length of the dielectric resonator and the capacitance of the additional capacitor so that the sum of each phase lead of the third harmonic in the connection terminal 108, at the additional capacitor and in the fifth dielectric resonator 503 falls within the range of (2n₅−1)π/2±5% (n₅ is a natural number except 3m−1, and m is a natural number).

The total axial length of the fifth and sixth dielectric resonators 503, 502 corresponding to (2n₆−1)λ/4 correspond to (2n₆−1)π/2 as the phase lead of the fundamental wave. In the case where the fifth and sixth dielectric resonators 503, 502 are connected to the connection end A through the aforementioned connection terminals 108 or via additional capacitors in the present embodiment, each phase lead in the connection terminals 108 to the dielectric resonators and the additional capacitors must be taken into consideration. Specifically, it is preferable for allowing the impedances for the second and third harmonics to be short-circuited under little-affected on the impedance of the fundamental wave to adjust the phase lead of the fundamental wave from the open end of the fifth dielectric resonator 503 to the grounded end of the sixth dielectric resonator 502 to fall within the range of (2n₆−1)π/2±5%. In other words, it is preferable to adjust the axial lengths of the dielectric resonators and the capacitance of the additional capacitors so that the sum of each phase lead in the fifth and sixth dielectric resonators 503, 502 and each phase lead in the connection terminals 108 to the dielectric resonators and the additional capacitors to fall within the range of (2n₆−1)π/2±5%.

### Embodiment 6

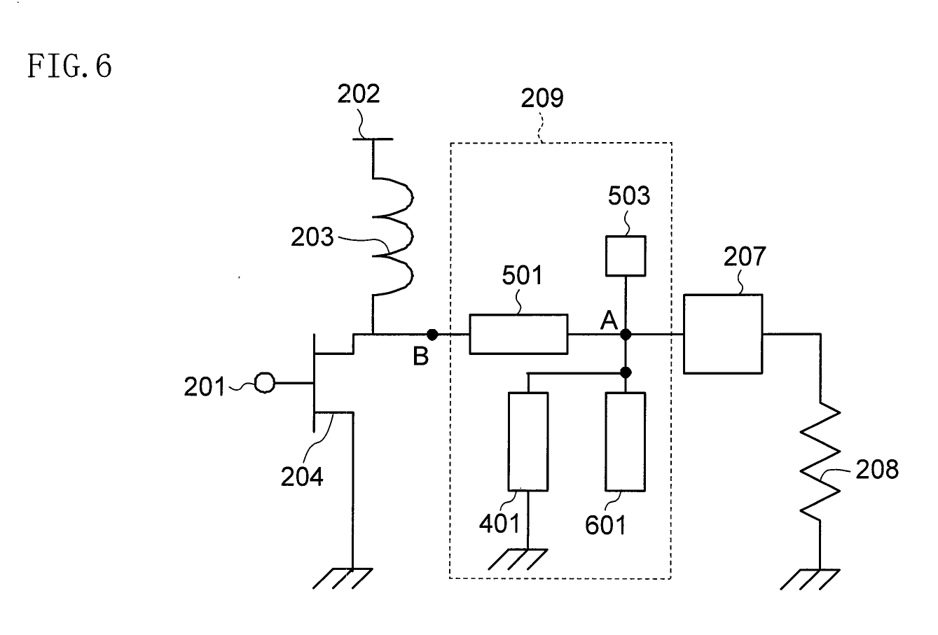

FIG. 6 is a circuit diagram of a high frequency power amplifier in accordance with Embodiment 6 of the present invention. The difference from Embodiment 5 of the present invention lies in that the sixth dielectric resonator 502 is replaced by a seventh dielectric resonator 601. The seventh dielectric resonator 601 is connected at one end thereof to the amplification element 204 via the connection end A, is opened at the other end, and is adjusted to have an axial length corresponding to 5λ/12.

As described in Embodiment 5 of the present invention, with the fourth dielectric resonator 401 and the fifth dielectric resonators 503, the impedances at an output end B of the amplification element 204 are short-circuited for the even harmonics short-circuited at the connection end A by the dielectric resonator 401 and are opened to the odd harmonics of the third, ninth, fifteenth, . . . , 3(2m−1)-th harmonics short-circuited at the connection end A by the dielectric resonator 503.

Further, with the fifth and seventh dielectric resonators 503, 601 of which total axial length corresponds to λ/2, the fundamental wave forms an amplitude loop at the open end of the fifth dielectric resonator 503 while forming an amplitude loop at the open end of the seventh dielectric resonator 601 for resonance. According to this resonance, the impedance for the fundamental wave at the connection end A to be almost infinite to allow the fundamental wave to pass through the harmonic control circuit 209. Hence, the harmonics short-circuited at the connection end A by the dielectric resonators are controlled while the impedance for the fundamental wave of the high frequency input signal is little-affected by the harmonic control circuit 209.

If the total axial length of the fifth and seventh dielectric resonators 503, 601 corresponds to n₇λ2 (n₇ is a natural number), the fundamental wave forms an amplitude loop at the open end of the fifth dielectric resonator 503 while forming an amplitude loop at the open end of the seventh dielectric resonator 601 for resonance. Accordingly, in the case where the signal frequency is high or the like, an increase in value of n₇ can lead to realization of a circuit in a practical size.

The total axial length of the fifth and seventh dielectric resonators 503, 601 corresponding to n₇λ/2 corresponds to n₇π as the phase lead of the fundamental wave. In the case where the fifth and seventh dielectric resonators 503, 601 are connected to the connection end A through the aforementioned connection terminals 108 or via additional capacitors in the present embodiment, it is preferable for allowing the impedance for the second and third harmonics to be short-circuited at the connection end A under little-affected on the impedance of the fundamental wave to adjust the phase lead of the fundamental wave from the open end of the fifth dielectric resonator 503 to the open end of the seventh dielectric resonator 601 to fall within the range of n₇π±5%. In other words, it is preferable to adjust the axial lengths of the dielectric resonators and the capacitance of the additional capacitors so that the sum of each phase lead in the fifth and seventh dielectric resonators 503, 601 and each phase lead in the connection terminals 108 to the dielectric resonators and at the additional capacitors to fall within the range of n₇π±5%.

### Embodiment 7

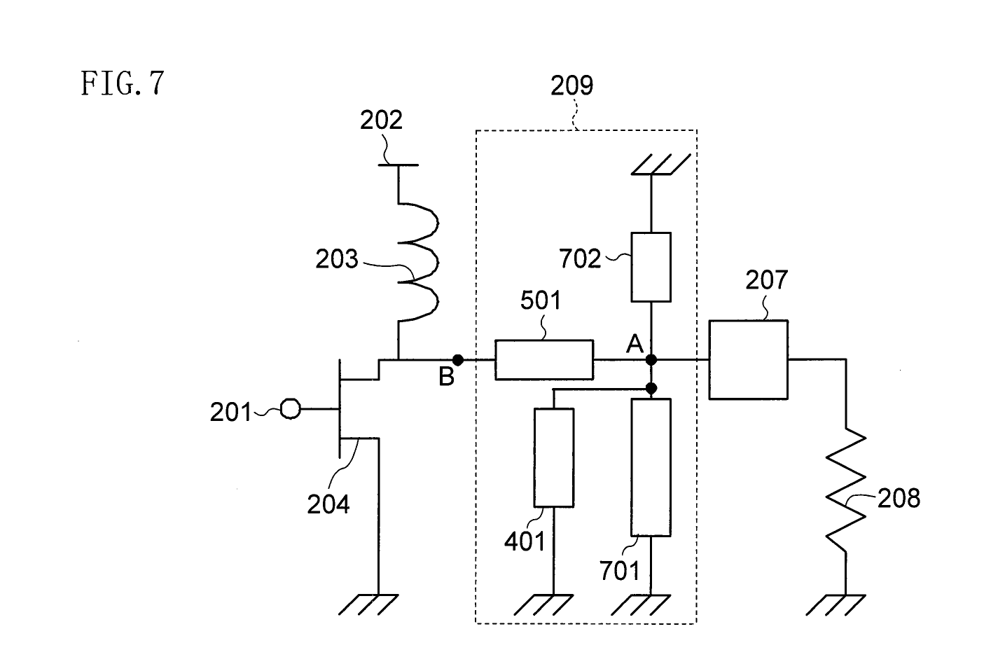

FIG. 7 is a circuit diagram of a high frequency power amplifier in accordance with Embodiment 7 of the present invention. In the present embodiment, the harmonic control circuit 209 includes the microstrip line 501, the fourth dielectric resonator 401, an eighth dielectric resonator 702, and a ninth dielectric resonator 701.

The eighth dielectric resonator 702 is connected at one end thereof to the connection end A, is grounded at the other end, and is adjusted to have an axial length corresponding to λ/6. The ninth dielectric resonator 701 is connected at one end thereof to the connection end A, is grounded at the other end, and is adjusted to have an axial length corresponding to λ/3.

The axial length of the eight dielectric resonator 702, which corresponds to λ/6, corresponds to λ₃/2 where the wavelength of the third harmonic is λ₃. Accordingly, the third harmonic wave forms an amplitude node at the grounded end while forming an amplitude node at the connection end A. This causes the impedance for the third harmonic wave to be short-circuited at the connection end A. Similarly, the impedances for the sixth, ninth, . . . , 3m-th harmonics are short-circuited at the connection end A.

The fourth dielectric resonator 401 sets the impedances for all the even harmonics to be short-circuited at the connection end A. As described in Embodiment 5, the phase is rotated by the microstrip line 501, and accordingly, the impedances at the output end B of the amplification element 204 are short-circuited for the even harmonics short-circuited at the connection end A by the dielectric resonator 401 and are opened to the odd harmonics short-circuited of the third, sixth, ninth, . . . , 3-m-th harmonics short-circuited at the connection end A by the dielectric resonator 702.

Further, with the eighth and ninth dielectric resonators 702, 701 of which total axial length corresponds to λ/2, the fundamental wave forms an amplitude node at the grounded end of the eighth dielectric resonator 702 while forming an amplitude node at the grounded end of the ninth dielectric resonator 701 for resonance. According to this resonance, the impedance for the fundamental wave at the connection end A to be almost infinite to allow the fundamental wave to pass through the harmonic control circuit 209. Hence, the harmonics short-circuited at the connection end A by the dielectric resonators are controlled while the impedance for the fundamental wave of the high frequency input signal is little-affected by the harmonic control circuit 209.

Even if the axial length of the eighth dielectric resonators 702 is adjusted so as to correspond to n₈λ/6 (n₈ is a natural number except multiples of 3), the third, sixth, ninth, . . . , 3m-th harmonics form amplitude nodes at the grounded end of the eighth dielectric resonator 702 while forming amplitude nodes at the connection end A. Hence, the impedances for the third, sixth, ninth, . . . , 3m-th harmonics can be short-circuited at the connection end A. As a result, even in the case where the axial lengths of the dielectric resonators are shortened due to a high signal frequency, an increase in value of n₈ can lead to realization of the harmonic control circuit 209 in a practical size.

Wherein, where ng is a multiple of 3, the fundamental wave forms an amplitude node at the grounded end while forming an amplitude node at the connection end A to inhibit the fundamental wave from passing through the harmonic control circuit 209. Therefore, n₈ must be prevented from being a multiple of 3.

When the total axial length of the eighth and ninth dielectric resonators 702, 701 corresponds to n₉λ/2 (n₉ is a natural number), the fundamental wave forms an amplitude node at the grounded end of the eighth dielectric resonator 702 while forming an amplitude node at the grounded end of the ninth dielectric resonator 701 for resonance. Accordingly, in the case where the signal frequency is high or the like, an increase in value of n₉ can lead to realization of a circuit in a practical size.

The axial length of the eighth dielectric resonator 702, which corresponds to n₈λ6, corresponds to n₈π as the phase lead of the third harmonic. In the case where the eighth dielectric resonator 702 is connected to the connection end A through the aforementioned connection terminal 108 or via an additional capacitor in the present embodiment, it is preferable for allowing the impedance for the third harmonic to be short-circuited at the connection end A to adjust the phase lead of the third harmonic from the connection end A to the grounded end of the eighth dielectric resonator 702 to fall within the range of n₈π±5% (n₈ is a natural number except multiples of 3). In other words, it is preferable to adjust the axial length of the dielectric resonator and the capacitance of the additional capacitor so that the sum of each phase lead in the connection terminal 108, at the additional capacitors and in the eighth dielectric resonator 702 falls within the range of n₈π±5% (n₈ is a natural number except multiples of 3).

The total axial length of the eighth and ninth dielectric resonators 702, 701 corresponding to n₉λ/2 corresponds to n₉π as the phase lead of the fundamental wave. In the case where the eighth and ninth dielectric resonators 702, 701 are connected to the connection end A through the aforementioned connection terminals 108 or via additional capacitors in the present embodiment, it is preferable for allowing the impedances for the second and third harmonics to be short-circuited under little-affected on the impedance of the fundamental wave to adjust the phase lead of the fundamental wave from the grounded end of the eighth dielectric resonator 702 to the grounded end of the ninth dielectric resonator 701 to fall within the range of n₉π±5%. In other words, it is preferable to adjust the axial lengths of the dielectric resonators and the capacitance of the additional capacitors so that the sum of each phase lead in the eighth and ninth dielectric resonators 702, 701 and each phase lead in the connection terminals 108 to the dielectric resonators and the additional capacitors to fall within the range of n₉π±5%.

### Embodiment 8

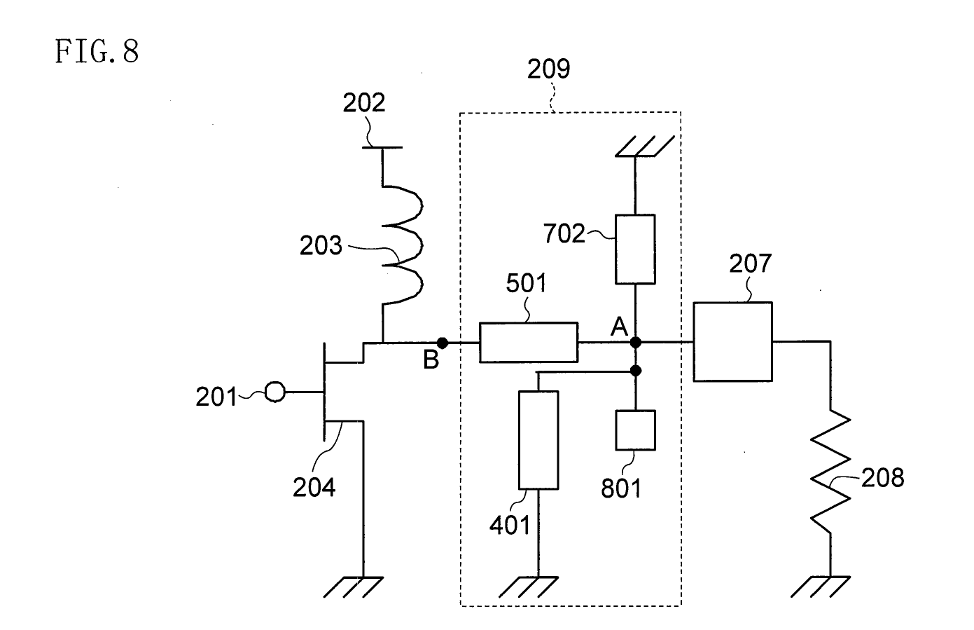

FIG. 8 is a circuit diagram of a high frequency power amplifier in accordance with Embodiment 8 of the present invention. The difference from Embodiment 7 lies in that the ninth dielectric resonator 701 is replaced by a tenth dielectric resonator 801. The tenth dielectric resonator 801 is connected at one end thereof to the connection end A, opened at the other end thereof, and is adjusted to have an axial length corresponding to λ/12.

As described in Embodiment 7, with the fourth dielectric resonator 401 and the eight dielectric resonator 702, the impedances at an output end B of the amplification element 204 are short-circuited for the even harmonics short-circuited at the connection end A by the dielectric resonator 401 and are opened to the odd harmonics of the third, sixth, ninth, . . . , 3m-th harmonics by the dielectric resonator 702.

Further, with the eighth and tenth dielectric resonators 702, 801 of which total axial length corresponds to λ/4, the fundamental wave forms an amplitude node at the grounded end of the eighth dielectric resonator 702 while forming an amplitude loop at the open end of the tenth dielectric resonator 801 for resonance. According to this resonance, the impedance for the fundamental wave at the connection end A to be almost infinite to allow the fundamental wave to pass through the harmonic control circuit 209. Hence, the harmonics short-circuited at the connection end A by the dielectric resonators are controlled while the impedance for the fundamental wave of the high frequency input signal is little-affected by the harmonic control circuit 209.

When the total axial length of the eighth and tenth dielectric resonators 702, 801 corresponds to (2n₁₀−1)λ/4 (n₁₀ is a natural number), the fundamental wave forms an amplitude node at the grounded end of the eighth dielectric resonator 702 while forming an amplitude loop at the open end of the tenth dielectric resonator 801 for resonance. Accordingly, in the case where the signal frequency is high or the like, an increase in value of n₁₀ can lead to realization of a circuit in a practical size.

The total axial length of the eighth and tenth dielectric resonators 702, 801, which corresponds to (2n₁₀−1)λ/4, corresponds to (2n₁₀−1)π/2 as the phase lead over the fundamental wave. In the case where the eighth and tenth dielectric resonators 702, 801 are connected to the connection end A through the aforementioned connection terminals 108 or via additional capacitors in the present embodiment, it is preferable for allowing the impedance for the second and third harmonics to be short-circuited at the connection end A under little-affected on the impedance of the fundamental wave to adjust the phase lead of the fundamental wave from the grounded end of the eighth dielectric resonator 702 to the open end of the tenth dielectric resonator 801 to fall within the range of (2n₁₀−1)π/2±5%. In other words, it is preferable to adjust the axial lengths of the dielectric resonators and the capacitance of the additional capacitors so that the sum of each phase lead in the eighth and tenth dielectric resonators 702, 801 and each phase lead in the connection terminals 108 to the dielectric resonators and at the additional capacitors to fall within the range of (2n₁₀−1)π/2±5%.

### Embodiment 9

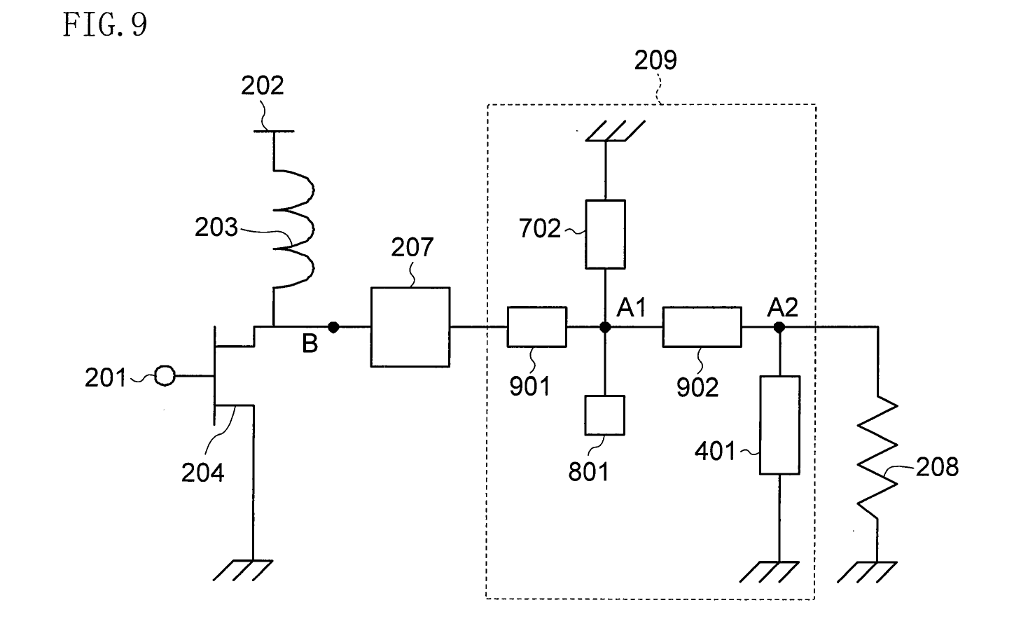

FIG. 9 is a circuit diagram of a high frequency power amplifier in accordance with Embodiment 9 of the present invention. The difference from Embodiment 8 lies in that the harmonic control circuit 209 and the output matching circuit 207 are arranged differently so that the output matching circuit 207 is connected to the output end B of the amplification element 204 and the harmonic control circuit 209 is connected to the output end of the output matching circuit 207. Further, the harmonic control circuit 209 includes a first strip line 901, a second strip line 902, and the fourth, eighth, and tenth dielectric resonators 401, 702, 801.

The output matching circuit 207 includes a circuit element having a capacitance and an inductance to cause phase rotation of the harmonics. Accordingly, for the second harmonic, the phase rotation of the second harmonic up to the point A2 that connects the fourth dielectric resonator 401 for controlling the second harmonic is adjusted in the harmonic control circuit 209 with phase rotation of the second harmonic in the output matching circuit 207 taken into consideration. Similarly, for the third harmonic, the phase rotation of the third harmonic up to the point A1 that connects the eighth and tenth dielectric resonators 702, 801 for controlling the third harmonic is adjusted in the harmonic control circuit 209 with phase rotation of the third harmonic in the output matching circuit 207 taken into consideration.

In the present embodiment, in order to satisfy the above load circuit conditions, the fourth dielectric resonator 401 is connected to a connection end A2 at which the sum of: the phase rotation of the second harmonic at the output matching circuit 207; the phase rotation thereof at each of the first and second microstrip lines 901, 902; and the phase rotation thereof at each of the eighth and tenth dielectric resonators 702, 801 is 2n₁₃π(n₁₃ is a natural number). Accordingly, the impedance for the second harmonic short-circuited at the connection end A2 by the fourth dielectric resonator 401 can be short-circuited also at the output end B of the amplification element 204.

Further, the eighth and tenth dielectric resonators 702, 801 are connected to the connection end A1 at which the sum of the phase rotation of the third harmonic at the output matching circuit 207 and the phase rotation thereof at the first strip line 901 is (2n₁₄−1)π (n₁₄ is an natural number). This allows the impedance for the third harmonic short-circuited at the connection end A1 by the eighth dielectric resonator 702 to be opened at the output end B of the amplification element 204.

The fourth dielectric resonator 401 for controlling the second harmonic is arranged near the load resistor 208 in the present embodiment, but the eighth and tenth dielectric resonators 702, 801 for controlling the third harmonic may be arranged near the load resistor 208 as long as the load circuit conditions are satisfied.

The above described embodiments are mere examples, and the present invention is not limited thereto. For example, replacement of the load resistor 208 by an antenna enables transmission of an amplified high frequency signal.

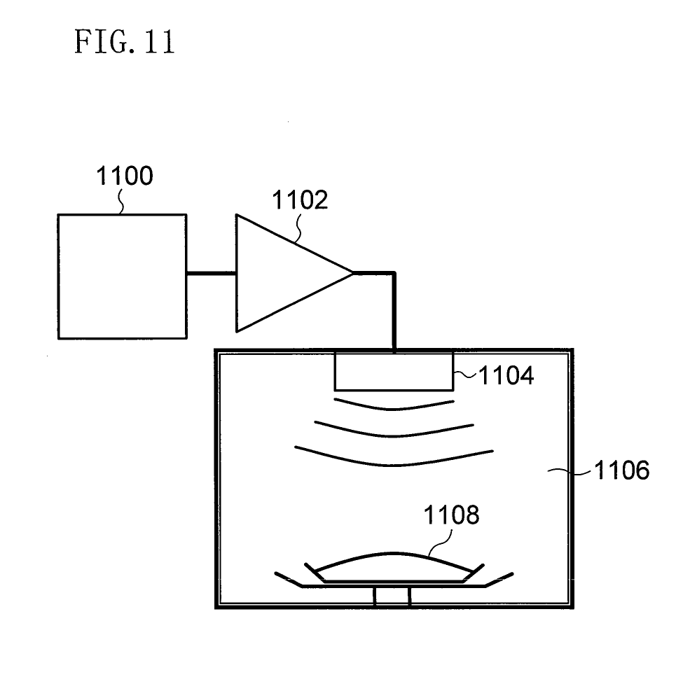

The transmission loss in a harmonic control circuit increases in association with the output of a high frequency power amplifier, and therefore, the present invention is useful in application that requires large output over 100 W, such as a high frequency heating device. For example, as shown in FIG. 11, a high frequency heating device may be composed of a high frequency oscillator 1100, a high frequency power amplifier 1102 according to the present invention which amplifies an output signal of the high frequency oscillator 1100, a container 1106 for accommodating a to-be-heated object 1108 and heating it at a electromagnetic wave amplified in the high frequency power amplifier 1102, and a high frequency radiator 1104, such as an antenna for radiating an output signal of the high frequency power amplifier 1102 inside the container 1106. With this construction, the power loading efficiency of the high frequency power amplifier 1102 is high to lead to an increase in heating efficiency and reduction in power consumption of the high frequency heating device.

As described above, the present invention is useful for reduction in size of a harmonic control circuit utilized for increasing the power efficiency of a high frequency power amplifier and for reduction in transmission loss.

What is claimed is:

1. A high frequency power amplifier, comprising:
an amplification element for amplifying a high frequency input signal; and
a harmonic control circuit connected to an output end of the amplification element and including a dielectric resonator.

2. The high frequency power amplifier of claim 1, wherein
the harmonic control circuit includes a first dielectric resonator connected at one end thereof to the output end of the amplification element via a connection end and being opened at the other end thereof, and
a phase lead of a second harmonic of the high frequency input signal from the connection end to the other end of the first dielectric resonator is adjusted so as to fall within a range of (2n₁−1)π/2±5% (n₁ is a natural number).

3. The high frequency power amplifier of claim 2, wherein
the harmonic control circuit further includes a second dielectric resonator of which one end is connected to the output end of the amplification element via the connection end and of which the other end is grounded, and
a phase lead of a fundamental wave of the high frequency input signal from the other end of the first dielectric resonator to the other end of the second dielectric resonator is adjusted so as to fall within a range of (2n₂−1)π/2±5% (n₂ is a natural number).

4. The high frequency power amplifier of claim 2, wherein
the harmonic control circuit further includes a third dielectric resonator of which one end is connected to the output end of the amplification element via the connection end and of which the other end is opened, and
a phase lead of the fundamental wave of the high frequency input signal from the other end of the first dielectric resonator to the other end of the third dielectric resonator is adjusted so as to fall within a range of n₃π±5% (n₃ is a natural number).

5. The high frequency power amplifier of claim 1, wherein
the harmonic control circuit includes a fourth dielectric resonator of which one end is connected to the output end of the amplification element via a connection end and of which the other end is grounded, and
a phase lead of a second harmonic of the high frequency input signal from the connection end to the other end of the fourth dielectric resonator is adjusted so as to fall within a range of (2n₄−1)π±5% (n₄ is a natural number).

6. The high frequency power amplifier of claim 1, wherein
the harmonic control circuit includes: phase rotation means connected between the output end of the amplification element and a connection end; and a fifth dielectric resonator of which one end is connected to the output end of the amplification element via the connection end and of which the other end is opened, and
a phase lead of a third harmonic of the high frequency input signal from the connection end to the other end of the fifth dielectric resonator is adjusted so as to fall within a range of (2n₅−1)π/2±5% (n₅ is a natural number except 3m−1 where m is a natural number).

7. The high frequency power amplifier of claim 6, wherein
the harmonic control circuit further includes a sixth dielectric resonator of which one end is connected to the output end of the amplification element via the connection end and of which the other end is grounded, and
a phase lead of a fundamental wave of the high frequency input signal from the other end of the fifth dielectric resonator to the other end of the sixth dielectric resonator is adjusted so as to fall within a range of (2n₆−1)π/2±5% (n₆ is a natural number).

8. The high frequency power amplifier of claim 6, wherein
the harmonic control circuit further includes a seventh dielectric resonator of which one end is connected to the output end of the amplification element via the connection end and of which the other end is opened, and
a phase lead of a fundamental wave of the high frequency input signal from the other end of the fifth dielectric resonator to the other end of the seventh dielectric resonator is adjusted so as to fall within a range of n₇π±5% (n₇ is a natural number).

9. The high frequency power amplifier of claim 1, wherein
the harmonic control circuit includes: phase rotation means connected between the output end of the amplification element and a connection end; and an eighth dielectric resonator of which one end is connected to the output end of the amplification element via the connection end and of which the other end is grounded, and
a phase lead of a third harmonic of the high frequency input signal from the connection end to the other end of the eighth dielectric resonator is adjusted so as to fall within a range of n₈π±5% (n₈ is a natural number except multiples of 3).

10. The high frequency power amplifier of claim 9, wherein
the harmonic control circuit further includes a ninth dielectric resonator of which one end is connected to the output end of the amplification element via the connection end and of which the other end is grounded, and
a phase lead of a fundamental wave of the high frequency input signal from the other end of the eighth dielectric resonator to the other end of the ninth dielectric resonator is adjusted so as to fall within a range of n₉π±5% (ng is a natural number).

11. The high frequency power amplifier of claim 9, wherein
the harmonic control circuit includes a tenth dielectric resonator of which one end is connected to the output end of the amplification element via the connection end and of which the other end is opened, and
a phase lead of a fundamental wave of the high frequency input signal from the other end of the eighth dielectric resonator to the other end of the tenth dielectric resonator is adjusted so as to fall within a range of (2n₁₀−1)π/2±5% (n₁₀ is a natural number).

12. The high frequency power amplifier of claim 6, wherein
the phase rotation means is a transmission line of which length is adjusted so as to correspond to a length in a range of (2n₁₁−1)λ/4 (n₁₁ is a natural number) where λ is a wave length of a fundamental wave of the high frequency input signal.

13. A high frequency heating device comprising:
a high frequency oscillator:
a high frequency power amplifier including: an amplification element which amplifies a high frequency signal output from the high frequency oscillator; and a harmonic control circuit including a dielectric resonator and connected to an output end of the amplification element;
a container for heating an object therein by radiating inside thereof with the high frequency signal amplified in the high frequency power amplifier; and
a high frequency radiator which radiates inside of the container with the high frequency signal output from the high frequency power amplifier.
